(19) United States
(12) Patent Application Publication
(10) Pub. No.: US 2025/0063795 A1
(43) Pub. Date: Feb. 20, 2025

(54) LOCAL TRAPPED METAL CONTACT FOR STACKED FET

(71) Applicant: International Business Machines Corporation, Armonk, NY (US)

(72) Inventors: Ruilong Xie, Niskayuna, NY (US); Brent A. Anderson, Jericho, VT (US); Albert M. Chu, Nashua, NH (US); Junli Wang, Slingerlands, NY (US); Jay William Strane, Wappingers Falls, NY (US)

(21) Appl. No.: 18/449,986

(22) Filed: Aug. 15, 2023

(51) Int. Cl. H01L 29/417; H01L 21/308; H01L 27/088; H01L 29/08; H01L 29/40; H01L 29/66

(52) U.S. Cl. CPC H01L 29/41725; H01L 21/308; H01L 27/088; H01L 29/0847; H01L 29/401; H01L 29/66545

(57) ABSTRACT

A semiconductor device includes a stacked transistor structure having field effect transistors on two levels. The two levels include a top side and bottom side. Active regions are disposed on the bottom side. The active regions include a recessed portion therein. A metal cap is disposed within the recessed portion. A contact is disposed within the metal cap to reduce contact resistance.

### BACKGROUND

The present invention generally relates to semiconductor devices and processing methods, and more particularly to stacked field effect transistors (FETs) with a trapped metal contact between FET layers.

Stacked transistor devices may be used to increase areal density of devices on a chip. Additionally, the close proximity of the overlying and underlying devices can be useful when forming paired devices, such as complementary semiconductor devices that include two devices of opposing polarity. However, positioning transistors above one another places spatial and electrical constraints that can make it challenging to provide required performance.

Stacked field effect transistors (FETs) formed can suffer from insufficient dielectric material separating top and bottom devices. In addition, spatial constraints can result in bottom devices not providing enough contact area between active regions and contacts to permit adequate electrical contact.

### SUMMARY

In accordance with an embodiment of the present invention, a semiconductor device includes a stacked transistor structure having field effect transistors on two levels. The two levels include a top side and bottom side. Active regions are disposed on the bottom side. The active regions include a recessed portion therein. A metal cap is disposed within the recessed portion. A contact is disposed within the metal cap to reduce contact resistance.

In accordance with another embodiment of the present invention, a method for fabrication of a semiconductor device includes forming dummy gate structures on a substrate, the gate structures forming channels therebetween, forming a protective liner along upper portions of the channels and epitaxially growing bottom source/drain regions on exposed portions of the substrate. A bottom interlevel dielectric layer (ILD) is deposited and recessed to expose portions of the bottom source/drain regions. A recess is formed in the bottom source/drain regions using the protective liner as a mask. The recess is filled with a conductive material to form a metal cap in the recess and top source/drain regions are formed. Dummy gates are replaced in the dummy gate structures by a replacement metal gate (RMG) process and a contact is formed to the metal cap.

In accordance with another embodiment of the present invention, a method for fabrication of a semiconductor device includes forming dummy gate structures on a substrate, the gate structures forming channels therebetween; forming a protective liner along upper portions of the channels; epitaxially growing bottom source/drain regions on exposed portions of the substrate; depositing a bottom interlevel dielectric layer (ILD); recessing the bottom ILD to expose portions of the bottom source/drain regions; forming a recess in the bottom source/drain regions using the protective liner as a mask; filling the recess with a conductive material to form a metal cap in the recess; forming top source/drain regions; recessing the metal cap to increase a space above the metal cap; filling the space above the metal cap with dielectric material to increase dielectric material between the top source/drain regions and the bottom source drain regions; replacing dummy gates in the dummy gate structures by a replacement metal gate (RMG) process; and forming a contact to the metal cap.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 shows cross-sectional views, taken at section lines X and Y as shown in an inset (and referred to as section X and section Y respectively), of a semiconductor substrate and a stack of layers that can be formed or provided in one or more nanosheets, in accordance with an embodiment of the present invention;

FIG. 2 shows cross-sectional views, taken at section lines X and Y, of the stack of layers patterned and a shallow trench isolation region formed, in accordance with an embodiment of the present invention;

FIG. 3 shows cross-sectional views, taken at section lines X and Y, of the stack of layers removed in section Y and dummy gate structures formed in section X, in accordance with an embodiment of the present invention;

FIG. 4 shows cross-sectional views, taken at section lines X and Y, after formation of sacrificial material used for the formation of upper channel protective liners, in accordance with an embodiment of the present invention;

FIG. 5 shows cross-sectional views, taken at section lines X and Y, after formation of the upper channel protective liners, in accordance with an embodiment of the present invention;

FIG. 6 shows cross-sectional views, taken at section lines X and Y, after removing the sacrificial material, in accordance with an embodiment of the present invention;

FIG. 7 shows cross-sectional views, taken at section lines X and Y, after epitaxially growing bottom active regions (e.g., S/D regions), in accordance with an embodiment of the present invention;

FIG. 8 shows cross-sectional views, taken at section lines X and Y, after depositing a bottom interlevel dielectric layer (ILD) and recessing the bottom ILD to expose top portions of the bottom active regions, in accordance with an embodiment of the present invention;

FIG. 9 shows cross-sectional views, taken at section lines X and Y, after etching a recess with arcuate surfaces into the bottom active regions using the protective liner as a mask, in accordance with an embodiment of the present invention;

FIG. 10 shows cross-sectional views, taken at section lines X and Y, after a conductive fill and recess to form metal caps within the recess with arcuate surfaces of the bottom active regions, in accordance with an embodiment of the present invention;

FIG. 11 shows cross-sectional views, taken at section lines X and Y, after the protective liners have been recessed down to the metal caps, in accordance with an embodiment of the present invention;

FIG. 12 shows cross-sectional views, taken at section lines X and Y, after metal caps have been further recessed to permit space for additional dielectric material and ensure additional isolation between top and bottom active regions, in accordance with an embodiment of the present invention;

FIG. 13 shows cross-sectional views, taken at section lines X and Y, after top active regions are formed, in accordance with an embodiment of the present invention;

FIG. 14 shows cross-sectional views, taken at section lines X and Y, after an interlevel dielectric layer is formed and planarized removing a hard mask over the dummy gate structures, in accordance with an embodiment of the present invention;

FIG. 15 shows cross-sectional views, taken at section lines X and Y, after a replacement metal gate process that replaces dummy gate material with a gate dielectric and gate conductor, in accordance with an embodiment of the present invention; and

FIG. 16 shows cross-sectional views, taken at section lines X and Y, after an interlevel dielectric layer is formed and etched and contacts formed to the metal cap, the bottom active regions and the top active regions, in accordance with an embodiment of the present invention.

### DETAILED DESCRIPTION

In accordance with embodiments of the present invention, devices and methods are described which include controlling dielectric separation between top and bottom epitaxial regions (epi regions) in a stacked field effect transistor (FET) device. In addition, trapped metal caps are provided which work in conjunction with contacts to contact epi regions to ensure increased surface contact surface area and reduce surface contact resistance (Rc).

In useful embodiments, a semiconductor device is provided by epitaxially growing an active region, e.g., a bottom active region (e.g., a bottom source/drain (S/D) region also referred to as an epi region) from a semiconductor substrate. The semiconductor device can include stacked FETs which have one transistor stacked (e.g., top FET) over another transistor (e.g., bottom FET) in a vertical region where the bottom S/D region is formed includes an ear spacer formed from a protective liner that lines a portion of sidewalls of gate structures. During fabrication, the bottom S/D region is etched to form an arcuate shaped recess therein. The arcuate shaped recess is formed by using the protective liner formed on the sidewalls of gate structures as a mask.

A metal cap is deposited within the arcuate shaped recess. The metal cap makes superior electrical contact with the bottom S/D region as the metal contact shares a greater surface area with the bottom S/D region than conventional contacts. In one embodiment, the metal capped is trapped between or within portions of the same bottom S/D region to provide a trapped contact. Since the metal cap is trapped within an individual S/D region, it can be considered a local trapped contact.

In one embodiment, the metal caps can be adjusted, e.g., by a recess process, to gain further space that separates bottom and top active regions (e.g., bottom and top S/D regions). When the space is filled with dielectric material better separation and dielectric isolation is provided between the bottom and top active regions of the stacked FET device. In another embodiment, contacts connecting to the bottom S/D region can connect to the metal cap, pass into the metal cap and/or pass through the metal cap into the material of the bottom S/D region.

In accordance with embodiments of the present invention, methods for forming a semiconductor device include forming a top channel protective liner or spacer. Etching the bottom S/D region to form arcuate shaped recesses using the protective line or spacer as a mask. A bottom S/D region metal cap is formed in the arcuate shaped recess. Processing continues by forming top side structures including top epi regions, replacement metal gates (RMGs), middle of the line (MOL) contacts, back end of the line (BEOL) structures and layers.

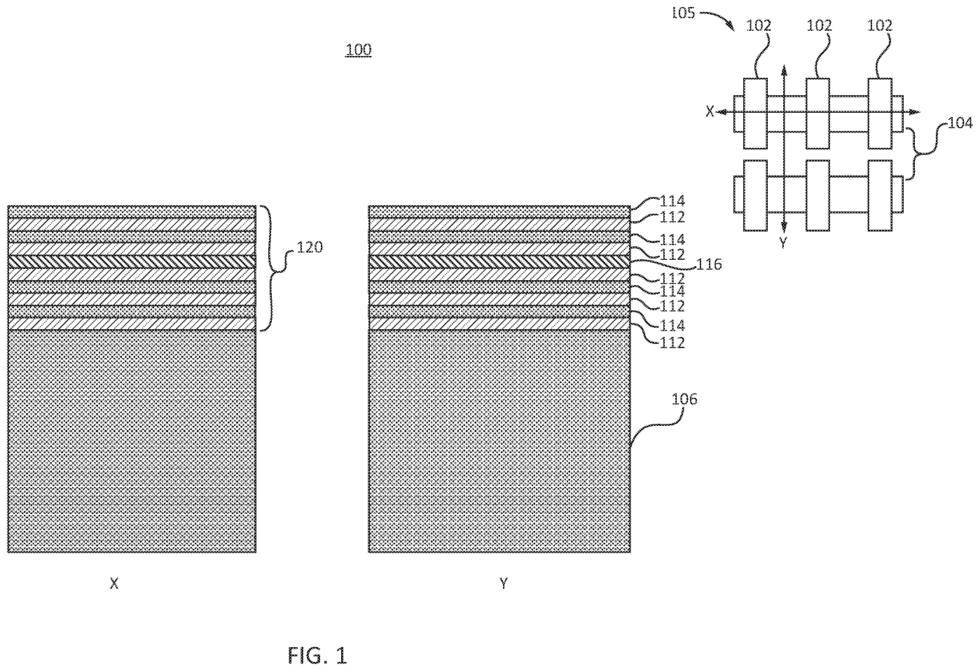

Referring now to the drawings in which like numerals represent the same or similar elements and initially to FIG. 1, devices and methods for manufacturing a stacked field effect transistor (FET) device are shown in accordance with embodiments of the present invention. A wafer 100 includes a substrate 106 having multiple layers on which the stacked FET device will be fabricated. FIG. 1 depicts two orthogonal views X and Y taken at corresponding section X and Y in inset 105. Inset 105 shows gate lines 102 and active regions lines 104 for reference. Corresponding X and Y views are depicted throughout FIGS. 1-16. Active region lines 104 represent channels (below gate lines 102), and S/D regions for transistor devices to be formed, and gate lines 102 are represented for such transistor devices.

The substrate 106 can include any suitable substrate structure, e.g., a bulk semiconductor, a semiconductor-on-insulator (SOI) substrate, etc., and preferably includes a monocrystalline semiconductor. In one example, the substrate 106 can include a silicon-containing material. Illustrative examples of Si-containing materials suitable for the substrate 106 can include, but are not limited to, Si, SiGe, SiGeC, SiC and multi-layers thereof. Although silicon is the predominantly used semiconductor material in wafer fabrication, alternative semiconductor materials can be employed as additional layers, such as, but not limited to, germanium, gallium arsenide, gallium nitride, silicon germanium, cadmium telluride, zinc selenide, etc.

A layer stack or stacks are applied to or formed on the substrate 106. In one embodiment, one or more nanosheets (NS) are applied to the substrate 106. In another embodiment, the layer stacks can be epitaxially grown using different chemistries to form layers having different properties. In an embodiment, a layer stack 120 includes a semiconductor layer 112 followed by a semiconductor layer 114, a semiconductor layer 112, a semiconductor layer 114, a semiconductor layer 112, a semiconductor layer 116, a semiconductor layer 112, a semiconductor layer 114, a semiconductor layer 112 and a semiconductor layer 114.

Each of semiconductor layers 112, 114 and 116 are selectively removeable relative to the others, e.g., by a selective etching process. In one embodiment, semiconductor layer 112 includes SiGe, where Ge is 30 atomic % of the compound; semiconductor layer 116 includes SiGe, where Ge is 55 atomic % of the compound, and semiconductor layer 114 includes Si. It should be understood that other materials or atomic percentages can be employed for semiconductor layers 112, 114 and 116. In other embodiments, different stack orders and numbers may be employed for semiconductor layers 112, 114 and 116.

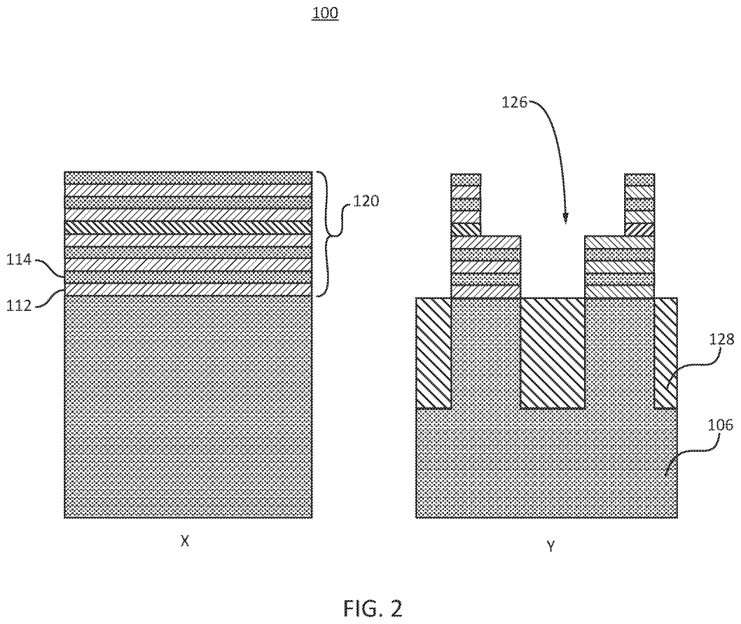

Referring to FIG. 2, whether a single or multiple nanosheets or an epitaxial grown layer stack are employed, the stack 120 can be patterned to expose and etch the substrate 106. In one embodiment, a hard mask (not shown) may be formed by blanket depositing a layer of hard mask material, providing a patterned photoresist on top of the layer of hard mask material, and then etching the layer of hard mask material to provide the hard mask pattern for etching the stack 120. The patterned photoresist can be produced by applying a blanket photoresist layer to the surface of the hard mask material and exposing the photoresist layer to a pattern of radiation, and then developing the pattern into the photoresist layer utilizing resist developer. The pattern in the photoresist layer is transferred to the hard mask by an etch process.

Opening 126 is formed through stack 120. Opening 126 can be formed using an anisotropic etch process, such as a reactive ion etch (RIE) or an ion beam etch (IBE). Substrate 106 is further etched to form shallow trenches therein in accordance with opening 126. Shallow trench isolation (STI) 128 is formed in the etched trenches. STI 128 can be formed by depositing dielectric material, such as, e.g., SiO₂, SiOₓN_{y}, SiCO or other suitable compounds. STI 128 can be deposited using chemical vapor deposition (CVD), although other deposition methods can be employed. The STI 128 can then be etched, e.g., by RIE, to a level of the substrate 106.

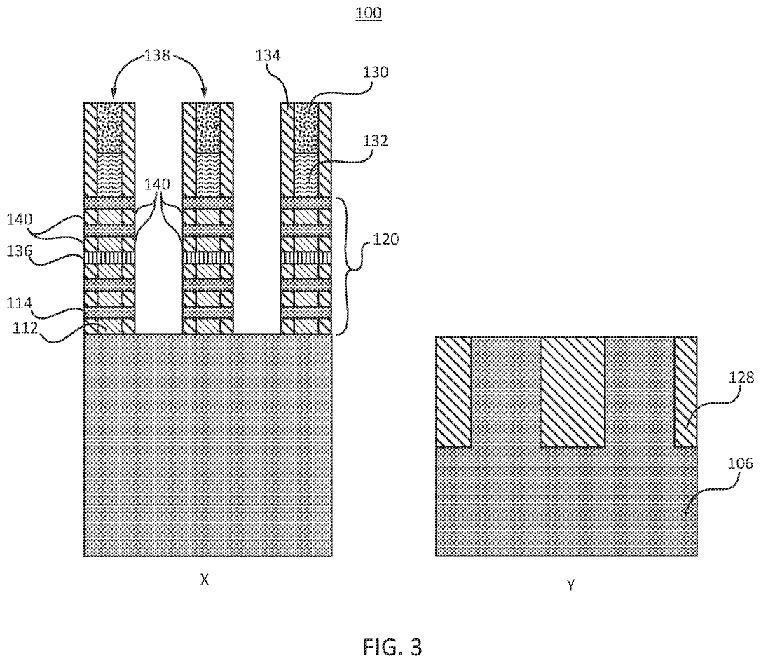

Referring to FIG. 3, a dummy gate material for dummy gates 132 is blanketed over the wafer 100 followed by a blanket deposition of a hard mask material to later form patterned hard mask 130, e.g., by using photolithographic patterning. The dummy gate material can include a polysilicon, amorphous Si or other selectively removeable material. Dummy gate structures 138 are patterned in accordance with the hard mask 130. The hard mask 130 is employed to etch the dummy gates 132. Semiconductor layer 116 is removed by a selective etch process by accessing the semiconductor layer 116 from the ends. Then, a deposition process is employed to form spacers 134 and middle dielectric isolation (MDI) 136 to fill empty regions where semiconductor layer 116 was removed. Spacers 134 and MDI 136 can include an oxide, such as silicon dioxide, although other dielectric materials can be employed.

The hard mask 130 and spacers 134 can be employed as an etch mask to recess the nanosheet (e.g., stack 120) to expose the substrate 106. Regions of the nanosheet below the hard mask 130 and spacers 134 are patterned for further processing while the nanosheet (e.g., stack 120) is completely removed in other regions.

Inner spacers 140 are formed and include a dielectric material. In one embodiment, the inner spacers 140 are formed using exposed portions of the semiconductor layer 112, which undergo a Ge condensation process to form a dielectric oxide (SiO₂) at the exposed portions by a thermal oxidation process. The oxidation process converts SiGe to the dielectric material (silicon oxide) and condenses out Ge.

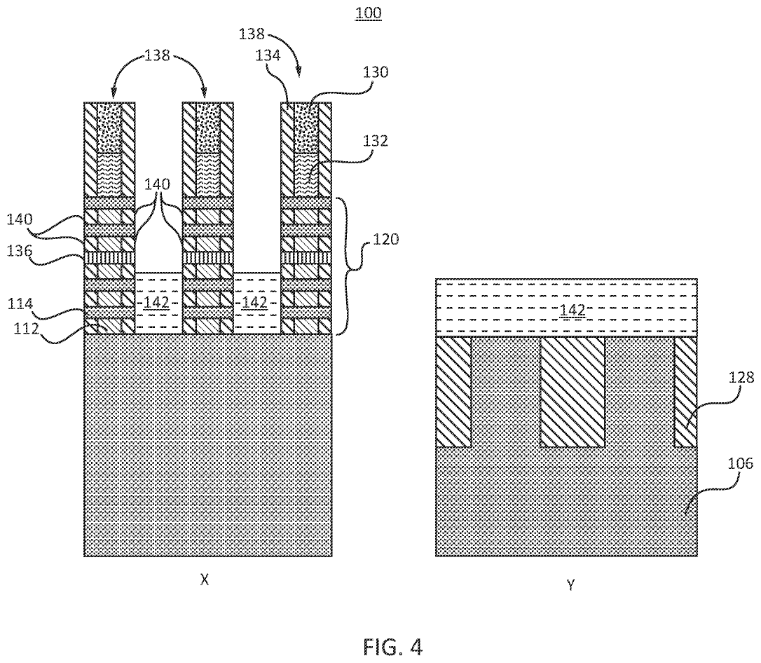

Referring to FIG. 4, a sacrificial material is deposited or spun onto a surface of the wafer 100. In one embodiment, an organic planarization layer (OPL) 142 is formed over the water 100. The OPL 142 is recessed to a level below the MDI 136 but covering the next semiconductor layer 114 below the MDI 136.

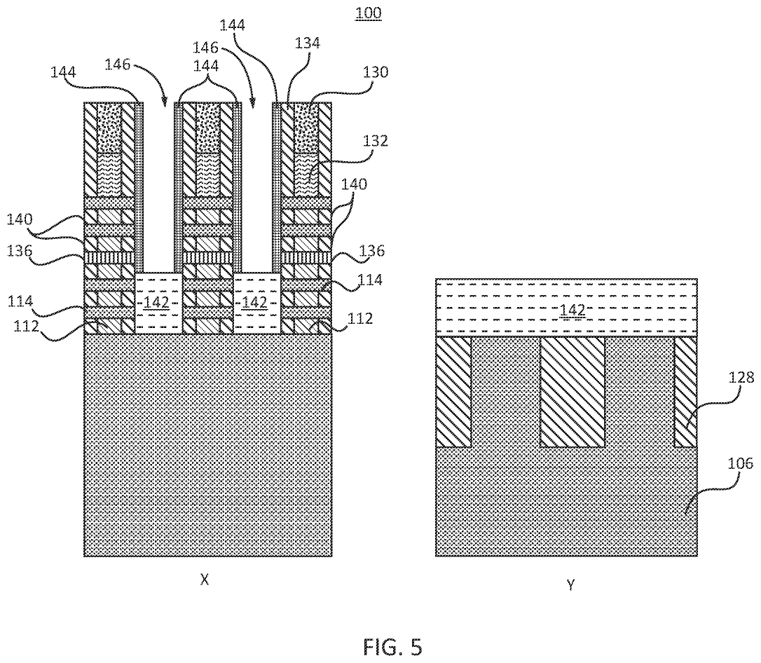

Referring to FIG. 5, a protective liner 144 is formed along sidewalls of channels 146 down to MDI 136. Protective liner 144 is formed by a conformal deposition of material (e.g., SiN). The protective liner 144 can be removed from horizontal surfaces by a selective etch, e.g., RIE, to remain in an upper region of channels 146.

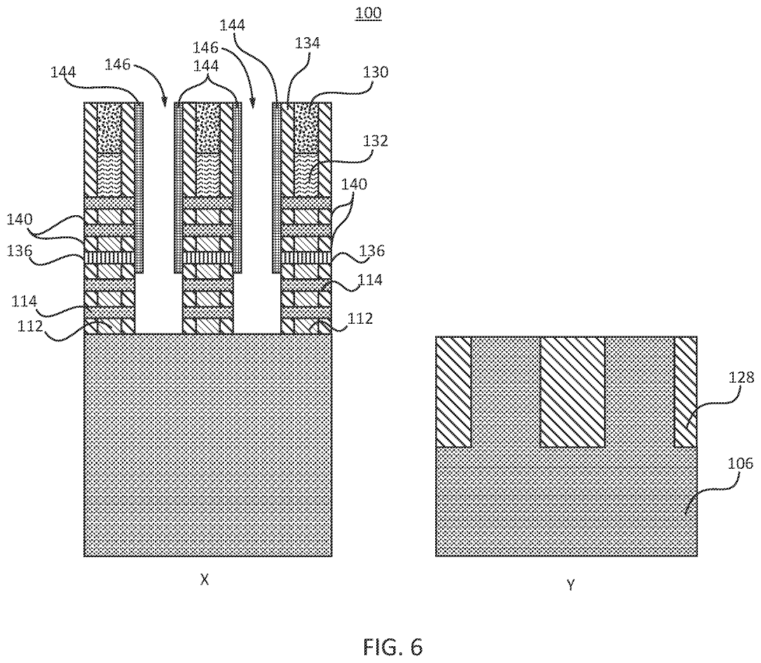

Referring to FIG. 6, the OPL 142 is removed. The OPL 142 can be removed by an ashing process, e.g., generating a reactive ion species, such as oxygen or fluorine, to react and remove the OPL 142.

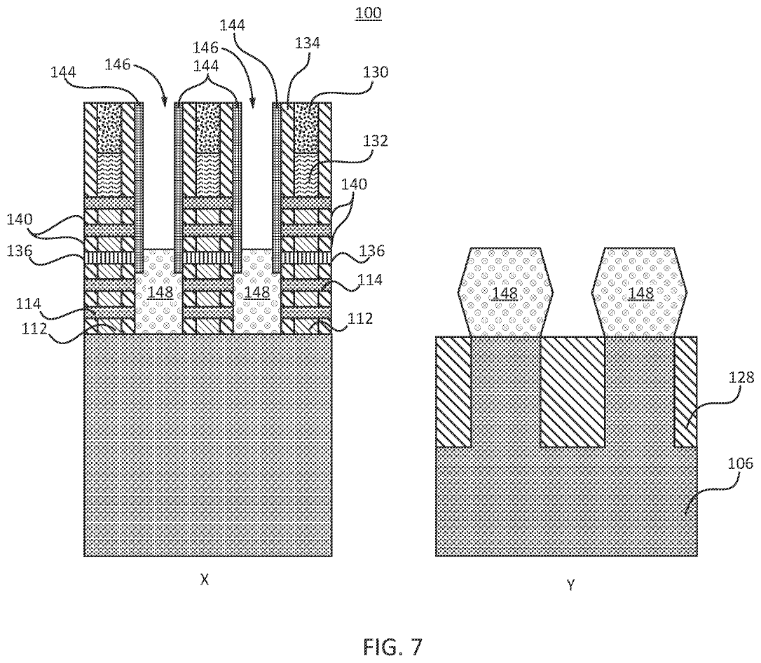

Referring to FIG. 7, an epitaxial growth process is performed to form bottom active regions 148 from exposed areas between STI 128 on the substrate 106. Bottom active regions 148 are employed to form source and drain (S/D) regions for bottom transistors of the stacked FET device under construction. Bottom active regions 148 can include Si or SiGe and include faceted surfaces when epitaxial growth is not confined. In one embodiment, the bottom active regions 148 can be designated as P-type or N-type devices. The P-type and N-type devices can have material selected for the bottom active regions 148. For example, if the bottom active regions 148 include N-type devices than the bottom active regions 148 can include Si. In another example, if the bottom active regions 148 include P-type devices then the bottom active regions 148 can include SiGe. The bottom active regions 148 can be appropriately doped during the formation of the bottom active regions 148 by epitaxial growth. For example, the bottom active regions 148 can be doped by introducing p dopants (e.g., B, Ga, etc.) during epitaxial formation. Similarly, the bottom active regions 148 can be doped by introducing n dopants (e.g., P, As, etc.) during epitaxial formation.

In other embodiments, P-type and N-type devices can be formed adjacent to one another. Processing would include forming one device type and then the other device type by employing block masks to protect each device during processing of the other.

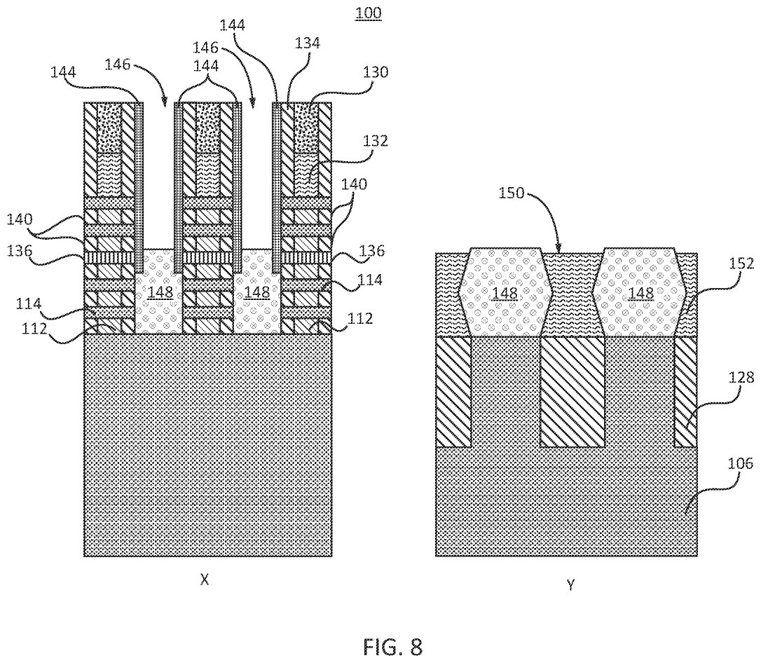

Referring to FIG. 8, a dielectric layer 152 is formed over the bottom active regions 148. The dielectric layer 152 can include any suitable material, e.g., selected from the group consisting of silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C: H). The dielectric layer 152 can be deposited using CVD, although other deposition methods can be employed.

The dielectric layer 152 is then recessed by an etch back process that removes the dielectric layer 152 evenly (level) across the wafer 100. The dielectric layer 152 is recessed to a surface 150 having a height below a height of the bottom active regions 148. The recessed dielectric layer 152 forms a bottom interlevel dielectric layer (ILD).

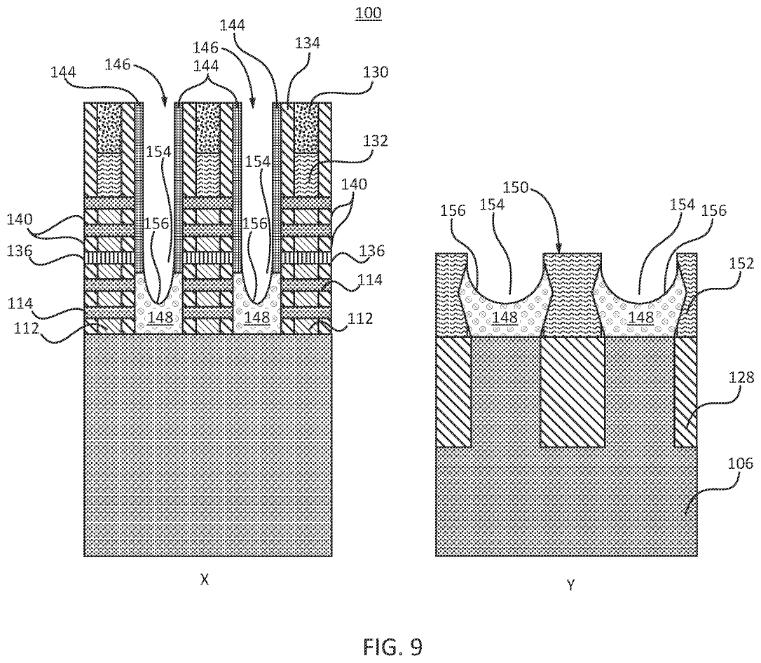

Referring to FIG. 9, a selective and accurately controlled epitaxial recess etch is employed to form a recess 154 in the bottom active regions 148. The recess etch can include an anisotropic etch, e.g., a reactive ion etch (RIE) etch or an ion beam etch (IBE) etch. In one embodiment, a timed plasma dry etch is employed. The recess 154 can include an arcuate curve, semicircle, or other bowed shape. The recess 154 is a compound shape and depends on the location of the bottom active regions 148. For example, the recess 154 in section Y is wider than the recess 154 in section X due to geometrical constraints during the recess etch process. Surfaces 156 resulting from the recess etch process provide increased surface area for electrical contact with later formed trapped contacts.

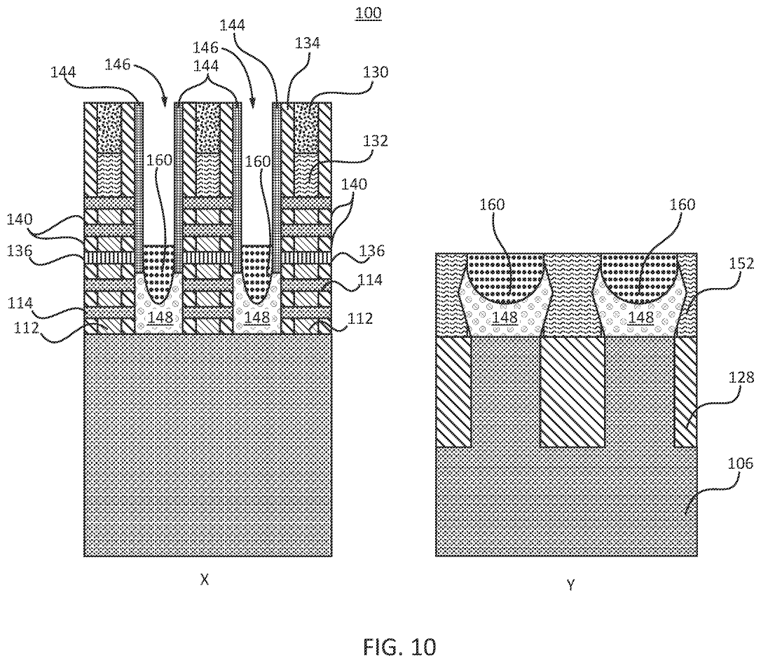

Referring to FIG. 10, a conductive fill is performed to fill the recess 154 on top of a diffusion barrier, if optionally present. The conductive fill can include materials, such as, e.g., a silicide liner such as Ti, Ni, NiPt, followed by an adhesion metal liner, such as TiN and a conductive metal fill, such as, e.g., W, Co, Ru, etc. The conductive fill can be formed using deposition methods, such as, e.g., CVD, plasma enhanced CVD (PECVD), atomic layer deposition (ALD) or any other suitable deposition method. The conductive fill is etched to recess the conductive material to form metal caps 160. The metal caps 160 are formed within and are self-aligned with the bottom active regions 148. The etch to recess the conductive material can include, e.g., plasma dry etch or wet etch. The sidewalls of the channels are protected by the protective liners 144 which mask the dummy gates features when recessing the metal caps 160.

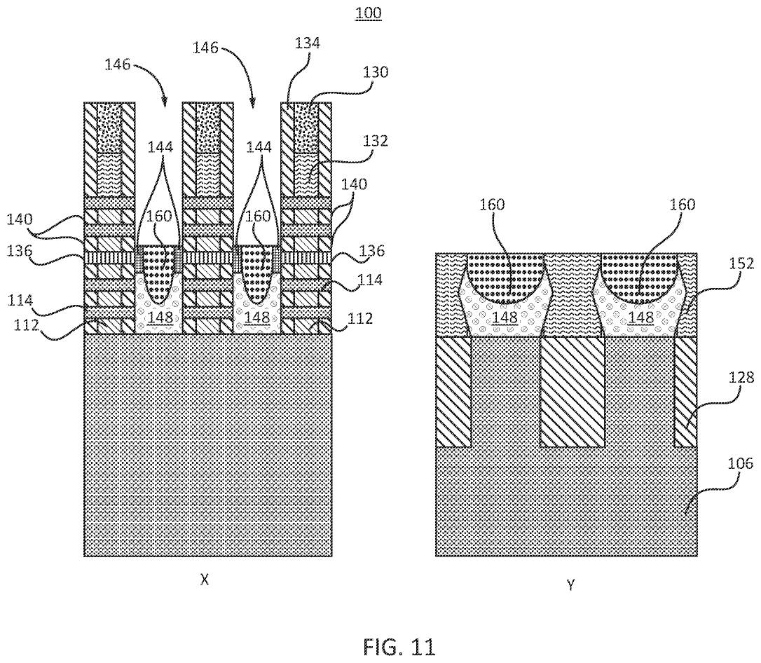

Referring to FIG. 11, portions of the protective liners 144 that remain exposed in channels 146 are removed. The exposed portions of the protective liner 144 are exposed to an etchant to selectively remove the protective liner 144 above a surface of the metal caps 160. The etchant can be introduced in a wet or dry etching process. In one embodiment, the remaining portions (ear spacers) of the protective liner roughly align with the MDI 136 in each channel 146.

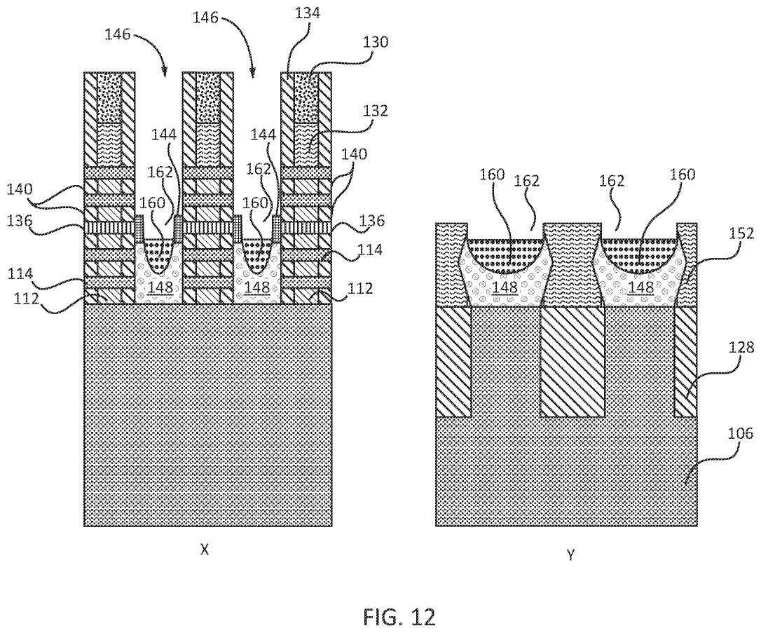

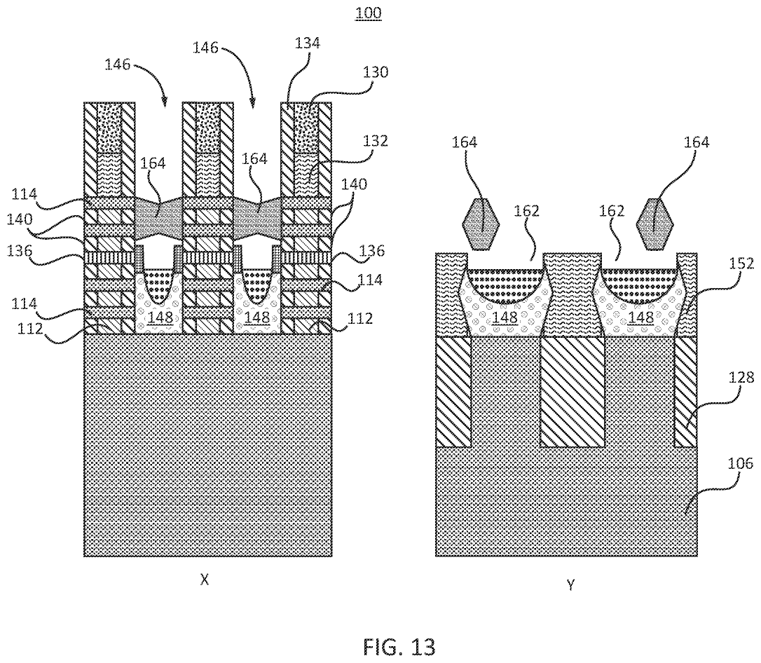

Referring to FIG. 12, in one embodiment, an additional recess 162 of the metal caps 160 can be performed. This recess 162 can provide additional separation between the bottom active regions 148 and top active regions 164 (FIG. 13) to be formed. The metal cap 160 can be size adjusted to permit additional dielectric material between the active regions on the bottom side and active regions of the top side of the device. A recess process can be employed to adjust the metal cap 160 and can include an anisotropic etch, e.g., RIE or IBE. The recess process etches the material of the metal cap 160 selective to the dielectric materials of the portions of the protective liners 144 that remain exposed in channels and bottom ILD (dielectric layer 152).

Referring to FIG. 13, whether or not the recess 162 is present, an epitaxial growth process is employed to grow top active regions 164. Top active regions 164 will form S/D regions for top FETs for the stacked FET device under fabrication. The top active regions 164 can utilize exposed semiconductor layers 114 to initiate crystal growth. The top active regions 164 will be separated from the bottom active regions 148 by a dielectric layer to be formed.

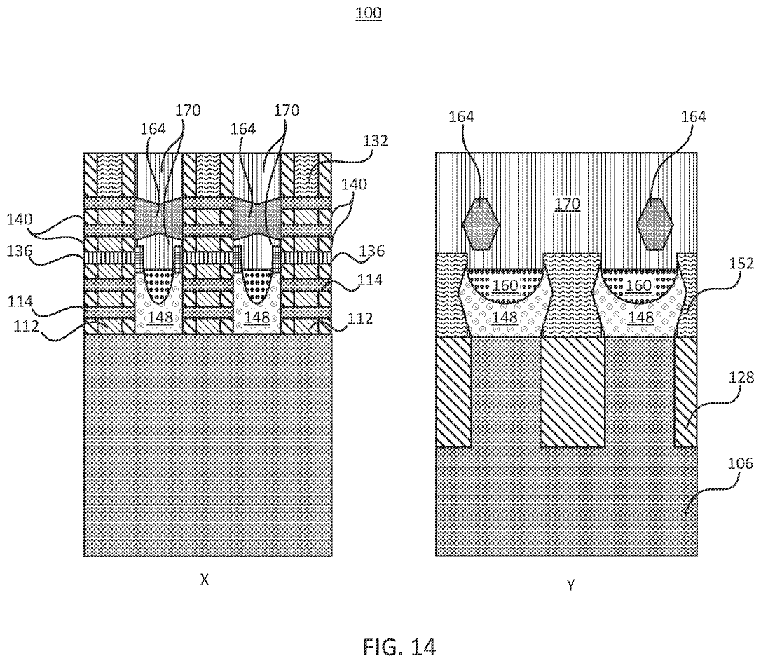

Referring to FIG. 14, a dielectric layer 170, such as, e.g., an interlevel dielectric layer (ILD) is formed on the wafer 100. The dielectric layer 170 can include any suitable material, e.g., selected from the group consisting of silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C: H). In one embodiment, the dielectric layer 170 includes a field oxide that can be deposited using CVD, although other deposition methods can be employed.

The wafer 100 is planarized to remove the hard mask 130, portions of the spacers 134 and to level the dielectric layer 170. In one embodiment, the planarization process can include a chemical mechanical polish (CMP). Dummy gates 132 are exposed for removal in the next process steps. The planarized dielectric layer 170 forms a top ILD layer.

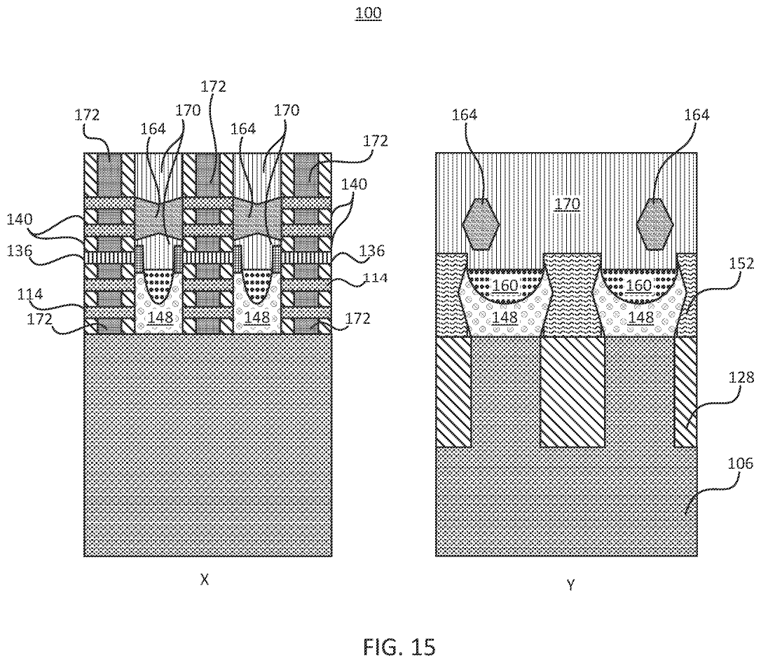

Referring to FIG. 15, dummy gates 132 and semiconductor layers 112 are removed by etching. This can include separate etch processes. The regions of the dummy gates 132 and the semiconductor layers 112 have a high dielectric constant (high-K) gate dielectric formed followed by a gate metal fill. This process is known as a replacement metal (RMG) gate process to replace dummy gates with a High-K Metal Gate (HKMG) structure 172 for selectively activating top FETs and bottom FETs associated with the bottom active regions 148 and the top active regions 164, respectively. The gate structures are separated by MDI 136 and the FETs are separated by the dielectric layer 170.

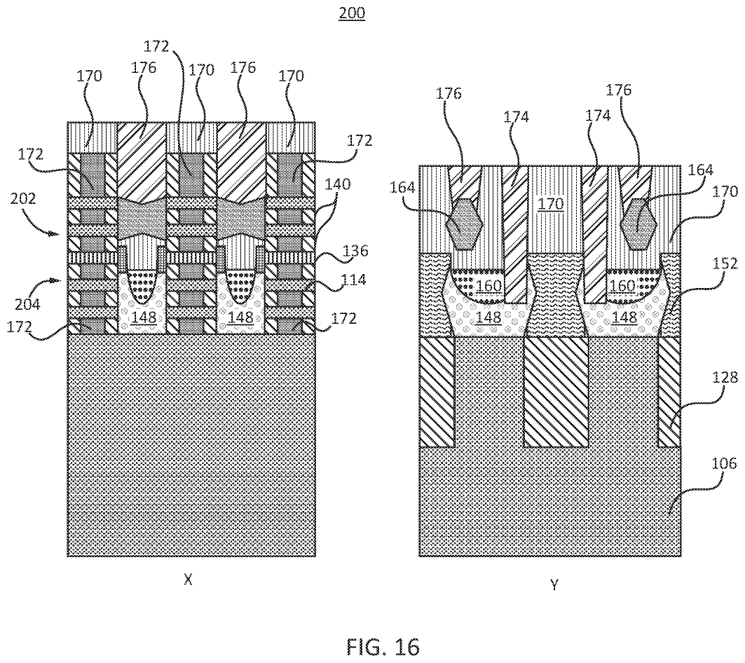

Referring to FIG. 16, middle of the line (MOL) contacts 174 and 176 are formed to make connections with the bottom active regions 148 from a top side of the device and the top active regions 164. Trenches or holes are formed in the dielectric layer 170, which forms a top ILD. The trenches or holes expose the underlying active materials for the active regions 164 and 148. In useful embodiments, a silicide liner such as Ti, Ni, NiPt is deposited first, then a diffusion barrier can be formed in the trenches prior to a conductive fill. The diffusion barrier can include, e.g., TiN, TaN, or similar materials.

A conductive fill is performed to fill the trenches on top of the diffusion barrier, if present. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, plasma enhanced CVD (PECVD), atomic layer deposition (ALD) or any other suitable deposition method. The conductive fill is planarized, e.g., by CMP, to form contacts 174, 176.

Contacts 174 are formed down into the metal caps 160 and into the epitaxial semiconductor portion of the bottom active regions 148. The contact 174 forms a low contact resistance connection to the bottom active regions 148. Contacts 174 can be referred to as trapped contacts as the contact once formed includes the metal cap 160 which is “trapped” between lateral portions of the bottom active regions 148. The metal cap 160 and the contact 174 together provide a high surface area contact with the bottom active regions 148 that reduces contact resistance.

Processing continues with the formation of back end of the line (BEOL) structures, which can include metal structures and dielectric layers to complete the top side of the stacked FET device and provide electrical access to the devices formed.

A semiconductor device such as a stacked FET device 200 is provided having FETs formed in at least two layers 202 and 204. Layers 202 and 204 are separated by dielectric layer 170. Top FETs include top active regions 164 functioning as S/D regions activated by gate 172 in layer 202. Bottom FETs include bottom active regions 148 functioning as S/D regions activated by gate 172 in layer 204. The bottom FETs include contact 174 to address contact resistance issues. The structure of the contact 174 includes a trapped metal cap 160 which increases surface area between the contact 174 and the bottom active region 148.

Exemplary applications/uses to which the present invention can be applied include, but are not limited to semiconductor devices. Semiconductor devices can include processors, memory devices, application specific integrated circuits (ASICs), logic circuits or devices, combinations of these and any other circuit device. In such devices, one or more semiconductor devices can be included in a central processing unit, a graphics processing unit, and/or a separate processor- or computing element-based controller (e.g., logic gates, etc.). The semiconductor devices can include one or more on-board memories (e.g., caches, dedicated memory arrays, read only memory, etc.). In some embodiments, the semiconductor devices can include one or more memories that can be on or off board or that can be dedicated for use by a hardware processor subsystem (e.g., ROM, RAM, basic input/output system (BIOS), etc.).

In some embodiments, the semiconductor devices can include and execute one or more software elements. The one or more software elements can include an operating system and/or one or more applications and/or specific code to achieve a specified result. In still other embodiments, the semiconductor devices can include dedicated, specialized circuitry that perform one or more electronic processing functions to achieve a specified result. Such circuitry can include one or more field programmable gate arrays (FPGAs), and/or programmable applications programmable logic arrays (PLAs).

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” “top,” “bottom” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of devices and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
a stacked transistor structure having field effect transistors on at least two levels, the at least two levels including a top side and bottom side;
active regions disposed on the bottom side, the active regions including a recessed portion therein;
a metal cap disposed within the recessed portion; and
a contact disposed within the metal cap to reduce contact resistance.

2. The semiconductor device as recited in claim 1, wherein the metal cap includes an arcuate shape.

3. The semiconductor device as recited in claim 1, wherein the contact includes a top side contact that passes through the top side to make contact with the metal cap.

4. The semiconductor device as recited in claim 1, wherein the contact passes through the metal cap and into material of the active regions disposed on the bottom side.

5. The semiconductor device as recited in claim 1, wherein the recessed portion is configured to include lateral portions and the metal cap is disposed between the lateral portions.

6. The semiconductor device as recited in claim 1, wherein the metal cap includes a size adjusted to permit additional dielectric material between the active regions on the bottom side and active regions of the top side.

7. The semiconductor device as recited in claim 1, wherein the metal cap includes a material selected from the group consisting of Cu, Ru, Mo, Rh, W, Ir, and alloys or combinations thereof.

8. A method for fabrication of a semiconductor device, comprising:
forming dummy gate structures on a substrate, the dummy gate structures forming channels therebetween;
forming a protective liner along upper portions of the channels;
epitaxially growing bottom source/drain regions on exposed portions of the substrate;
depositing a bottom interlevel dielectric layer (ILD);
recessing the bottom ILD to expose portions of the bottom source/drain regions;
forming a recess in the bottom source/drain regions using the protective liner as a mask;
filling the recess with a conductive material to form a metal cap in the recess;
forming top source/drain regions;
replacing dummy gates in the dummy gate structures by a replacement metal gate (RMG) process; and
forming a contact to the metal cap.

9. The method as recited in claim 8, wherein forming the recess in the bottom source/drain regions using the protective liner as a mask includes etching arcuate surfaces in the bottom source/drain regions.

10. The method as recited in claim 9, wherein the arcuate surfaces include lateral sides of the recess in the bottom source/drain regions and the metal cap is formed within the lateral sides of the recess.

11. The method as recited in claim 9, wherein forming contacts to the metal cap includes forming the contact through the metal cap and into the bottom source/drain regions.

12. The method as recited in claim 8, wherein the metal cap includes an arcuate shape.

13. The method as recited in claim 8, further comprising recessing the metal cap to increase a space above the metal cap.

14. The method as recited in claim 13, further comprising filling the space above the metal cap with dielectric material to increase dielectric material between top source/drain regions and bottom source drain regions.

15. The method as recited in claim 8, wherein the dummy gate structures include a middle dielectric isolation (MDI) region that separates a top gate portion from a bottom gate portion, and forming the protective liner along upper portions of the channels includes forming the protective liner along upper portions of the channels to the MDI region.

16. A method for fabrication of a semiconductor device, comprising:
forming dummy gate structures on a substrate, the dummy gate structures forming channels therebetween;
forming a protective liner along upper portions of the channels;
epitaxially growing bottom source/drain regions on exposed portions of the substrate;
depositing a bottom interlevel dielectric layer (ILD);
recessing the bottom ILD to expose portions of the bottom source/drain regions;
forming a recess in the bottom source/drain regions using the protective liner as a mask;
filling the recess with a conductive material to form a metal cap in the recess;
forming top source/drain regions;
recessing the metal cap to increase a space above the metal cap;
filling the space above the metal cap with dielectric material to increase dielectric material between the top source/drain regions and the bottom source/drain regions;
replacing dummy gates in the dummy gate structures by a replacement metal gate (RMG) process; and
forming a contact to the metal cap.

17. The method as recited in claim 16, wherein forming the recess in the bottom source/drain regions using the protective liner as a mask includes etching arcuate surfaces in the bottom source/drain regions.

18. The method as recited in claim 17, wherein the arcuate surfaces include lateral sides of the recess in the bottom source/drain regions and the metal cap is formed within the lateral sides of the recess.

19. The method as recited in claim 17, wherein forming contacts to the metal cap includes forming the contact through the metal cap and into the bottom source/drain regions.

20. The method as recited in claim 17, wherein the dummy gate structures include a middle dielectric isolation (MDI) region that separates a top gate portion from a bottom gate portion, and forming the protective liner along upper portions of the channels includes forming the protective liner along upper portions of the channels to the MDI region.
